(19) United States
(12) Patent Application Publication
(10) Pub. No.: US 2006/0267574 A1
(43) Pub. Date: Nov. 30, 2006

(54) Method for providing comprehensive electrical usage and demand data

(76) Inventor: John E. Howard, Ventura, CA (US)

Correspondence Address: John E. Howard, 1559 Spinnaker Drive #201, Ventura, CA, 93001, US

(21) Appl. No.: 11/412,267

(22) Filed: Apr. 26, 2006

Related U.S. Application Data
(60) Provisional application No. 60/675,068, filed on Apr. 26, 2005.

(51) Int. Cl. G01R 19/00

(52) U.S. Cl. 324/103 R

(57) ABSTRACT

A method for providing comprehensive electrical usage and demand data is disclosed. An electric meter (20), central data server (28), and customer's computer (38) comprise an Internet-based energy information system according to certain of the prior art. It is assumed that either or both of the networks (24, 36) of this system are intermittently connected, as in a dial-up connection, or are expensive to connect continuously, thereby precluding the presentation of real-time data. The present invention provides continuous, real-time data to a utility customer's computer through a direct, low-latency network (102) to the meter. All data are presented in the form of web pages, and the posted pages (30) and the locally generated pages ( ) are hyperlinked to one another, so that the customer has seamless access to comprehensive usage and demand data thereby, enabling proactive management of energy utilization. Further disclosed is a pulse transponder/logger that implements the system at a site with a pulse-output electric meter. Finally disclosed are algorithms to determine electrical demand trends from pulse streams.

### CROSS-REFERENCE TO RELATED APPLICATIONS

This application claims the benefit of provisional patent application Ser. No. 60/675,068, filed Apr. 26, 2005 by the present inventor.

### FEDERALLY SPONSORED RESEARCH

Not Applicable

SEQUENCE LISTING OR PROGRAM

Not Applicable

### BACKGROUND

1. Field of Invention

The field of the invention relates generally to the utilization of electrical power, and specifically to providing comprehensive electrical usage and demand data, including real-time data, to utility customers.

2. Description of Prior Art

The two primary components of electrical bills are usage charges and demand charges. Usage refers to the quantity of electrical energy consumed, and it is measured in kilowatt-hours (kWh). Demand is the rate (that is, the pace) at which energy is consumed, and it is measured in kilowatts (kW). Usage is often metered for each of a sequence of equal metering intervals, usually 15 minutes or one hour long. This is done for two reasons. First, usage charges can vary by the time of use, and the usage of each interval, or a particular block of intervals, can be billed at a different rate. Second, usage data are a convenient basis for demand charges. Demand charges are generally calculated from the highest average demand from any of the intervals that comprise a specified block of intervals. The average demand for an interval is simply the usage during that interval, expressed on an hourly basis. For the commonly used 15-minute interval, the usage would be multiplied four to get the hourly demand. Reactive power may be metered as well, and the corresponding units for usage and demand are kilovolt-Ampere-hours (kVAh) and kilovolt-Amperes (kVA), respectively.

Usage and demand charges and other charges are specified in utility tariffs, which are approved by a regulatory agency. In the past these tariffs remained more or less stable for a number of years, with periodic adjustments for the utility's costs of purchased power and power plant fuel.

More recently, various types of dynamic pricing, such as real-time energy pricing, have been introduced. Dynamic pricing provides market transparency that exposes customers to the time variations in energy costs, encouraging them to shift their usage into periods of lower prices. Dynamic pricing is being increasingly used mitigate power shortages and, in this context, it is referred to as “price response” or “demand response,” but the latter designation will be used elsewhere in this application. Many areas of the U.S. are beginning to rely heavily on this strategy to accommodate the growth in electrical demand and to maintain the reliability of electrical service on a regional level. Utilities and their regulators have implemented demand response as electric tariffs or formal programs, which provide incentives to reduce electrical demand during power shortages (“events”). In some cases, these incentives are contingent upon a customer reducing usage below some prescribed limit during each hour or each metering interval. If the customer fails to observe these limits, the incentives may be lost, harsh penalties may be imposed, or both.

Typically, the total demand of a facility fluctuates markedly, due to the many individual electrical loads turning on and off at irregular intervals. To reliably hit a demand target, a customer or an automatic control system needs real-time electrical usage and demand data. Here, and throughout this application, the term “real-time” shall mean timely such that a customer can proactively manage electrical usage and demand within each metering interval. In practical terms, such data must be updated multiple times in each interval.

To properly manage energy use, a customer needs both historic and real-time data, that is, comprehensive data. The historic data are useful to forecast operational trends, identify anomalous peaks, estimate utility bills, and the like.

Prior to the availability of remote-reading capability, utility personnel had to physically visit a meter and either manually or electronically read the usage and demand data from it. Most often, meter reading was performed on a monthly basis. Since then electric meters have been introduced that can be read remotely by one of five ways:
(a) mobile wireless communication, whereby a vehicle equipped with a limited-range, two-way radio is driven near, and communicates with, a meter that is also equipped with a two-way radio
(b) fixed wireless communication, which employs a fixed wireless network to communicate with a meter that is equipped with a two-way radio. These fixed wireless networks may be dedicated to meter reading, or they may also serve pagers or cellular telephones.
(c) satellite, which is similar to (a) and (b), but employs orbiting or geosynchronous communications satellites
(d) telephone, in which a modem-equipped meter is connected to and communicates through the public switched telephone network
(e) a network connection, which can use various communication media to connect the meter to the utility, so as to communicate nearly instantaneously and upon demand, consistent with the necessary bandwidth being available at the concentrated end, that is, the utility.

Remote meter reading and the development of the Internet have created the potential to provide customers with usage data that are updated throughout each month, and indeed many utilities offer Internet-based energy information services. These services may or may not provide real-time data, depending upon the latency of the remote-reading data path. Fixed wireless, satellite, and telephone access can theoretically approach real-time frequencies, but the communication service fees for thousands of accesses each month would become very costly, or even prohibitive. As an example of this limitation, a major utility, Southern California Edison Company (SCE), employs a large fleet of electric meters with fixed wireless and telephone access. Yet, the utility declared in testimony the California Public Utilities Commission in Application A.05-01, dated Jan. 20, 2005: “Due to technical and timing limitations, SCE cannot provide simultaneous real-time information to all approximately 13,000 large customers at this time.” It is impractical to access mobile wireless meters much more frequently than once per month.

A solution to the latency problem is the network-connected meter, which a utility can access frequently enough to provide real-time data at low cost. But, network meters are not an immediate and universal solution for at least three reasons. First, even though the number is growing, not all homes and businesses have the requisite network connection. Second, adding real-time capability will dramatically increase the utility's burden in supporting its Internet-based information system. Furthermore, this burden can be expected to peak during demand response events, when the need for real-time data is most acute, leaving the information system most vulnerable to failure. Third, utilities now have large investments in modem-equipped and fixed-wireless electric meters, as well as legacy (non-remotely read) meters. Electric meters have relatively long economic lives, typically 15 years, and premature replacement can strand the utility's investment in them, leading to higher electrical rates. The challenge is to utilize these electric meters for their remaining economic lives, while providing real-time data to the customers that have them.

The Internet-based information services that utilities offer their customers typically work in the following manner: the utility remotely accesses data from a customer's meter, composes one or more web pages that contain the data in textual or graphic form, and then posts the web page or pages for that customer, and its other customers, on a server. The customer's computer runs browser software that downloads from the server those web pages representing his or her meter readings, and presents the pages in viewable form on the computer's monitor. The web page format is attractive because of the ubiquity of computers with both Internet connections and browser software, such as Microsoft Internet Explorer and Netscape. A key aspect of the Internet is that these web pages and their graphical, textual, and programmatic content can be drawn from anywhere on the Internet, or from the customer's own computer. In some cases the web pages may be accompanied by data files not intended for viewing, but for further processing or archiving. The utility may either provide this information service itself or contract with a third party to do so.

U.S. Pat. No. 6,327,541 to Pitchford, et al. (2001) describes an Internet-based energy information system along the lines described. The patent cites the potential for providing customers real-time and near-real-time data, necessitating a low-latency data path between the meter and the utility's server, but only high-latency paths exist in many cases.

U.S. Pat. No. 6,178,362 to Woolard, et al. (2001) also describes an Internet-based information system, but one that is also capable of control. The claims cover not only the overall configuration, but also the presentation of data and the logistics of managing the data flows from large numbers of customers. Woolard, et al. asserts real-time performance, as in Pitchford, et al., again necessitating a low-latency data path between the meter and the utility's server.

U.S. Pat. No. 6,636,893 to Fong (2003) is derivative of Woolard, et al., of which Fong is co-inventor. Fong is distinct in employing a method referred to as “Web-bridging” in which one system (or customer) may be logged onto other multiple customers. As in the parent patent, Fong also requires a low-latency data path.

U.S. Patent Application 20040243524 to Crichlow (2004) describes an Internet-based energy information system, and asserts that it can provide real-time data, but rather than using a communicative electric meter, Crichlow adds an external element, an “automated meter reader,” which reads the meter and communicates the readings to a server.

U.S. Pat. No. 6,088,659 to Kelley, et al. (2000) pertains to an automated meter reading system, specifically one that obtains data from meters equipped with modems via standard telephone lines or public wireless networks. The patent acknowledges the latency of the data path by distinguishing between when data are recorded and when they are viewed, a characteristic labeled “asynchronous.”

U.S. Patent Application 20050024234 to Brooksby, et al. (2005) describes the cost-saving features of an electric meter with local communication, through which the utility can configure the meter, but the application does not state that the meter can communicate electrical usage data to the customer.

Demand data are essentially a snapshot of a customer's operation, and serve no purpose in preparing electric bills, which are based only upon logged usage data. On the other hand, the measurement of demand can be essential in the management of energy, and particularly for demand response.

The electric meter may have a portal to communicate usage data, and possibly demand data, to an application within the customer's premises. Commercial energy management systems, which monitor and control demand, are frequently communicative with electric meters of this type. Such a scheme application is disclosed in U.S. Pat. No. 5,924,486 to Ehlers, et al. (1999). In one implementation, Ehlers includes a communication path for energy provider notification of demand response events, but the invention does not capitalize upon the economies of scale of an Internet-based energy information system.

Electric meters can produce usage and demand signals to energy management system (EMS) or other external devices. These signals are typically in the form of “KYZ” pulses, as they are known in the electric utility industry. The pulses are produced by a device within the meter called a pulse initiator, which transmits one pulse each time a certain amount of usage is metered. This amount is known as the pulse constant, and is expressed as kilowatt-hours per pulse. The EMS determines real-time demand by counting the KYZ pulses produced during a running time period, one minute, for example. This technique is straightforward and obvious, and it serves the purpose of the EMS. But, for demand response applications, the technique has the drawback that sudden changes in demand will not be fully realized for as long as one entire time period. The customer or the automatic controls, as the case may be, will lose valuable time in waiting for changes in demand to register. If the time period is shortened, then the resolution of the demand measurement can suffer because fewer pulses will be counted. Decreasing the pulse constant will increase the pulse rate, allowing the time period to be shortened for better responsiveness. But, many EMSs log pulse counts in their data memory, and too many pulses within a metering interval can overflow the capacity of a memory element, corrupting the stored data.

The salient question is how to cost-effectively utilize the large, existing stock of electric meters without network capability to provide real-time usage and demand data to utility customers, in addition to high-latency and historic data from an Internet-based information system. Prior art does not provide the answer.

### OBJECTS AND ADVANTAGES

The method for providing comprehensive electrical usage and demand data of the present invention give utility customers the information they need to track their demand within each metering interval and to observe demand limits. The customers can thereby perform effectively in demand response programs, and avoid costly demand spikes, both of which will reduce their electrical bills. Lacking real-time demand measurements, the customers are flying blind and tend to over-respond to make sure they earn incentives, avoid penalties, or both. But, over-responding is undesirable because it can be disruptive to their operations.

Most demand response programs are optional. As participation in these programs grows, demand response will assume critical importance for maintaining the reliability and integrity of the electrical grid. The method for providing comprehensive electrical usage and demand data will not only allow customers to perform more effectively in the programs, but also reduce their risks associated with under-performance. Mitigating these risks can increase participation, compounding the beneficial effect upon grid reliability.

The method for providing comprehensive electrical usage and demand data are preferably implemented as extensions of a utility's existing Internet-based energy information service, which enhances the present invention's cost-effectiveness. The invention can extend the useful lives of some of the existing stock of electric meters, which would otherwise have to be replaced prematurely with network-capable meters to fully support demand response.

There are no recurring costs associated with the use of the method for providing comprehensive electrical usage and demand data. On the other hand, fixed-wireless and telephone systems have recurring costs in the form of communication service charges, and these charges bear a direct relationship to the frequency of access. For example, the aforementioned Southern California Edison Company charges its customers $2,940 per year to provide 15-minute updates under its tariff Schedule CC-DSF.

The algorithms that are part of alternative embodiments of the method for providing comprehensive electrical usage and demand data are highly responsive to changes in a customer's electrical demand, and allow the customer or automated controls to more time to take corrective action.

Still further objects and advantages will become apparent from a consideration of the ensuing description and drawings.

### SUMMARY

The Method for providing comprehensive electrical usage and demand data is described. According to the prior art, Internet-based energy information systems upload electric usage and demand data from communicating electric meters, and generate web pages, which the customer can download and view on a computer. In many cases the upload or download processes use dial-up or two-way wireless communication, which is adequate to transport historic data, but too slow or intermittent for real-time data.

The present invention overcomes the delay and the intermittency by adding a low-latency connection between the electric meter and the computer. Real-time data are transported through this connection and are locally composed into web pages. Thus, both historic, downloaded web pages and real-time web pages are brought into the computer and viewed by means of browser software. Pages are hyperlinked so that the customer navigates among them seamlessly. Having access to comprehensive, that is both historic and real-time, data enables the customer to proactively manage energy use.

Also disclosed is a device to generate real-time time usage and demand data from a meter with a KYZ pulse output. Further disclosed are algorithms for deriving useful real-time usage and demand data from the KYZ pulses.

### DRAWING—FIGURES

In the drawings, prior art elements bear reference numbers less than 100, and elements of the embodiments of method for providing comprehensive electrical usage and demand data bear reference numbers of 100 and greater. In the drawings:

FIG. 1 is a block diagram showing the method by which a utility provides electrical usage data to its customer by means of an Internet-based energy information system according to certain of the prior art. In this and the other figures, this customer is representative of a plurality of utility customers served by this type of information system.

FIG. 2 depicts a representative web page of an Internet-base energy information system according to certain of the prior art.

FIG. 3 is a block diagram showing the Internet-based energy information system of FIG. 1, incorporating an embodiment of the method for providing comprehensive electrical usage and demand data according to the present invention.

FIG. 4 depicts a representative web page that would be displayed according to an embodiment of the method for providing comprehensive electrical usage and demand data.

FIG. 5 is a block diagram of the pulse transponder and logger component employed by an alternative embodiment of the method for providing comprehensive electrical usage and demand data.

FIG. 6A, FIG. 6B, and FIG. 6C show the technique for determining the instantaneous electrical demand and the trend demand for a metering interval, which is employed by an embodiment of the method for providing comprehensive electrical usage and demand data.

FIG. 7A and FIG. 7B show an technique for determining the trend demand for a metering interval by using a linear regression, which is employed by an alternative embodiment of the method for providing comprehensive electrical usage and demand data.

### DRAWINGS—REFERENCE NUMERALS

| | |
|---|---|
| 20 | electric meter |
| 22 | meter communication portal |
| 24 | first network |
| 28 | data server |
| 30 | posted web pages (one or a plurality) |
| 36 | second network |
| 38 | customer's computer |
| 42 | browser software |
| 50 | premises |
| 52 | representative posted web page |
| 54 | toolbar of posted web pages |
| 56 | navigation button of posted web |
| | pages (a plurality) |
| 58 | menu of posted web pages |
| 100 | meter's local communication port |
| 102 | third network |
| 104 | software module |
| 106 | local web pages (one or a plurality) |
| 108 | toolbar of local web pages |
| 110 | navigation button of local web pages |
| | (a plurality) |
| 112 | menu of local web pages |
| 120 | pulse transponder/logger |
| 122 | KYZ pulse initiator |
| 124 | KYZ pulse connection |
| 130 | microcontroller |
| 132 | clock source |
| 134 | signal conditioning circuit |
| 136 | non-volatile data memory |
| 138 | communication interface |
| 140 | port (a plurality) |
| 142 | external power source |
| 144 | power connection |
| 146 | power supply |
| 146 | power supply |
| 148 | backup power source |
| 200 | KYZ pulse waveform |
| 202 | instantaneous demand, in kilowatts |
| 204 | linear regression trend |

### DESCRIPTION—PREFERRED EMBODIMENT

The description that follows is intended to be exemplary, and not limiting.

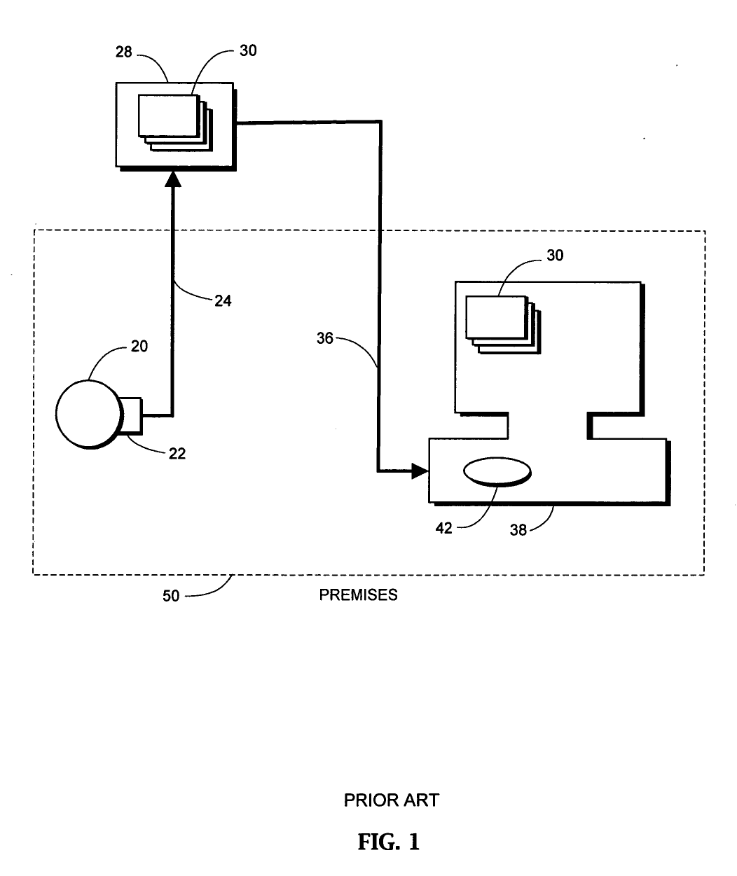

FIG. 1 is a block diagram illustrating the principle of an Internet-based energy information system that represents certain implementations of prior art, particularly those that are suitable for the application of the method for providing comprehensive electrical usage and demand data of the present invention. The premises 50 and the elements within it represent one of a plurality of similar premises occupied by utility customers who are served by the information system. An electric meter 20 measures the quantity of electrical energy used within the premises. A meter communication portal 22 is contained within the meter 20, or operatively connected to it, so as to communicate usage data through the first network 24 to the utility's data server 28. The data typically consist of the energy usage for each of a consecutive series of time intervals, which have a known correlation with local clock time and date. Such data are known as “interval data” in the electric utility industry. The utility processes the interval data into one or a plurality of web pages 30 for each customer and posts them onto the data server. The data server and customer's computer 38 are communicative through a second network 36, which is generally the public network known as the Internet. Communication through the first network is, in many cases, by dial-up or two-way wireless communication. The second network is typically continuously connected and high-speed, but it may be an intermittent, dial-up connection. The computer runs browser software 42, which manages the downloading of the posted web pages and depicts them in a form meaningful to the person using the computer.

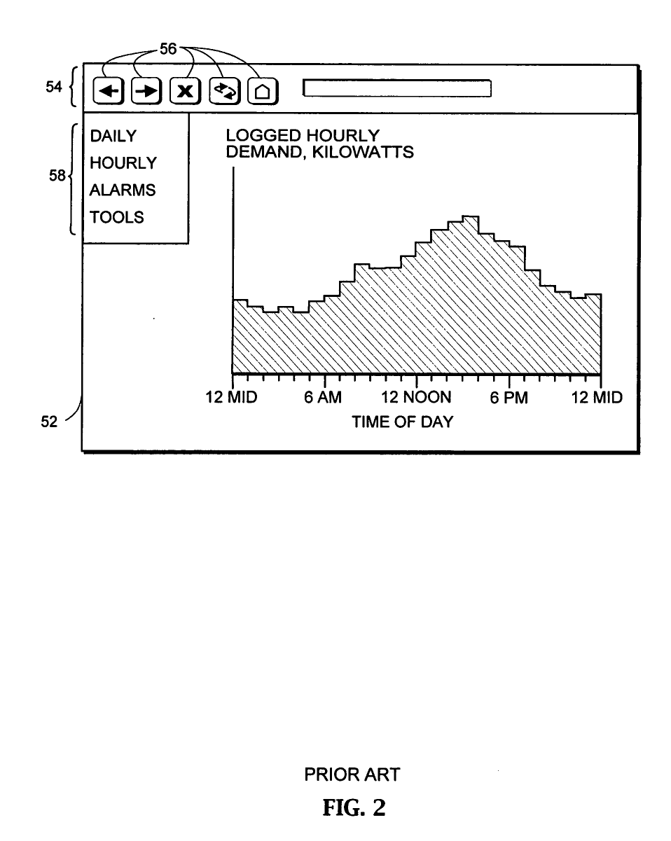

FIG. 2 shows a representative posted web page 52 as displayed by browser software on the customer's computer 38 according to certain of the prior art. The page includes toolbar 54 containing a plurality of navigation buttons 56 and a menu 58 that enable the customer to quickly move among the web pages comprising the utility's Internet-based energy information system pertaining to that customer. FIG. 2 specifically depicts in graphical form customer's electrical usage for each hour of a calendar day, based upon data that utility has uploaded from meter 20. Other web posted pages may depict, or be based upon, data from sources other than the customer's premises 50, such as energy pricing data, administrative data, and configuration data.

The details of these operations may differ in different implementations of the prior art, but the salient characteristic is that the high latency of communication through first network 24, or the second network 36, or both, prevents customer's timely access to the posted web pages 30 to fulfill the real-time criterion defined in [0004].

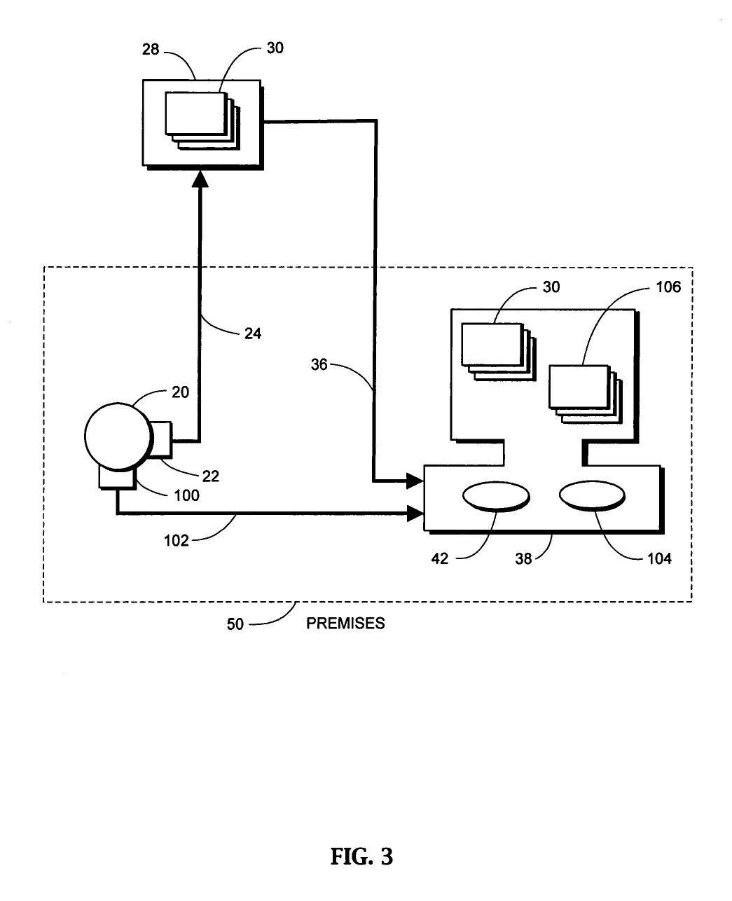

FIG. 3 is a block diagram showing the Internet-based energy information system depicted in FIG. 1, with the addition of an embodiment of the method for providing comprehensive electrical usage and demand data according to the present invention. The major elements added within premises 50 are a local communication port 100 for the meter 20; a third network 102; a software module 104; and, one or a plurality of locally generated web pages 106.

The meter 20 is communicative with the customer's computer 38 through meter's local communication port 100 and the third network 102. The third network may part of a larger multi-purpose network or a point-to-point connection. The computer runs software module 104, which has at least two functions: managing communications with meter 20, and composing one or a plurality of local web pages 106 based upon data received from the meter. Unlike the data in the posted web pages 30, which incorporate data moved with significant time delay, the data contained in the local web pages 106 are available through the third network upon request, with negligible latency, and conform to the definition of real-time data.

The arrows in the networks 24, 36, and 102 indicate data movement in one direction, although in practice the communication in these paths may be bidirectional so as to implement polling, handshaking, security protocols, and so forth.

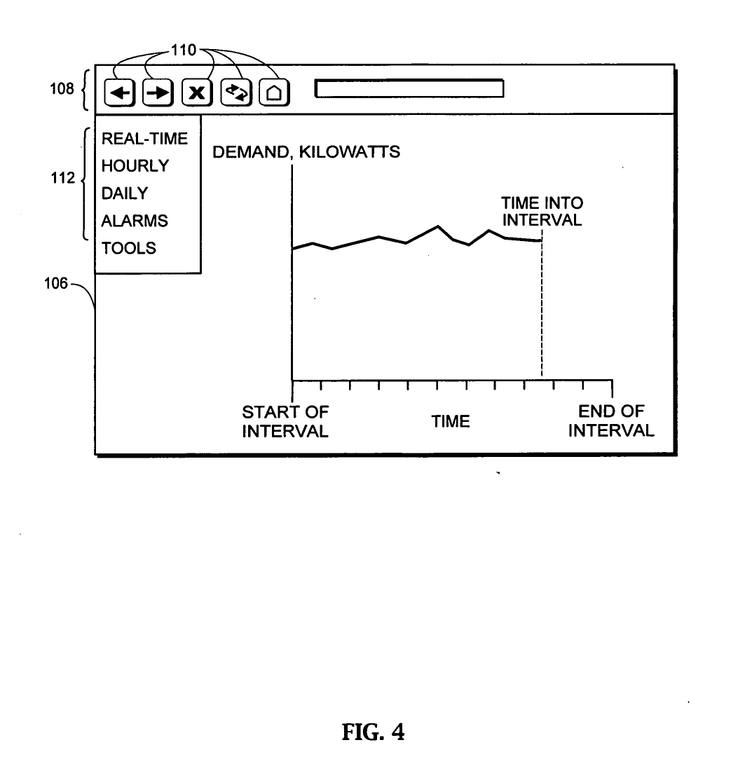

FIG. 4 depicts a representative local web page 106 as displayed by browser software on customer's computer 38, as part of the method for providing comprehensive electrical usage and demand data according to the present invention. This page and others comprising local web pages 106 include a toolbar 108 containing a plurality of navigation buttons 110 and a menu 112 that enable the customer to quickly move among any of the posted web pages 30 and local web pages 106 pertaining to that customer. FIG. 4 specifically depicts a graph of customer's electrical demand and usage during a metering interval, which is updated multiple times within the interval, that is, in real time. Other local web pages 106 may depict usage data for completed metering intervals for which posted web pages are not yet available. A representative way of composing local web pages would be as ActiveX documents, which are dynamic web pages created in Microsoft Corporation's Visual Basic programming environment.

### Description—Alternative Embodiments

The descriptions of alternative embodiments to method for providing comprehensive electrical usage and demand data that follow are intended to be exemplary, and not limiting.

Referring to FIG. 3, a first alternative embodiment places the software module 104, which composes the local web pages 106, in the meter 20 instead of the computer 38. This embodiment is applicable where the meter is equipped with a reprogrammable microcontroller that can compose and serve web pages, which is within the realm of current art.

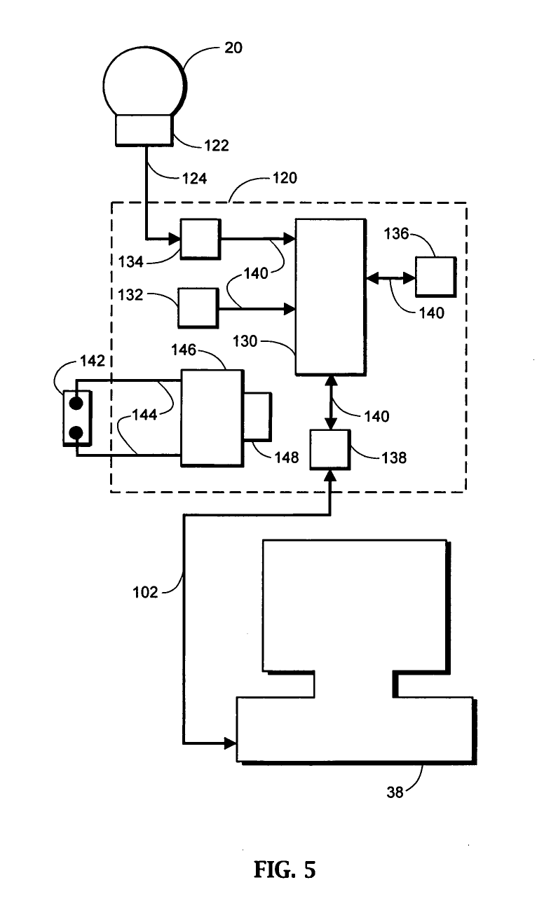

FIG. 5 is a block diagram of the pulse transponder/logger 120 of a second alternative embodiment, in which the demand signal from the meter 20 is in the form of KYZ pulses rather than the textual or numeric data of the preferred embodiment. The pulses are generated by a pulse initiator 122 which is an accessory added onto the meter or built into it. Within the pulse transponder/logger 120 is a microcontroller 130 that has a plurality of ports 140. The microcontroller runs an operating program that carries out certain monitoring, data storage, and communication functions. A clock source 132 provides a timing signal that paces the execution of the operating program. A pulse connection 124 conveys the KYZ pulses from the pulse initiator to a signal conditioning circuit 134, which circuit converts the pulses to a form and voltage level compatible with the specifications of the microcontroller. A non-volatile memory 136 stores interval data derived from the KYZ pulses. A communication interface 138 converts data signals between the microcontroller and the computer 38 to compatible levels and formats. As in the preferred embodiment, a third network 102 conveys these data signals to the computer 38. The clock source 132, signal conditioning circuit 134, non-volatile memory 136, and communication interface 138—collectively “peripherals”—are communicative with microcontroller 130 through a plurality of ports 140. One or more of these peripherals may be incorporated as an integral part of microcontroller 120. An external power source 142 delivers power to operate the pulse transponder/logger 120 through a power connection 140 to a power supply 146, which converts the power into voltage levels and current suitable and adequate for circuitry within pulse-transponder/logger. A backup power source 148 maintains timekeeping and logging functions operating during a loss of external power source 142 due to outages of the electric service or other cause.

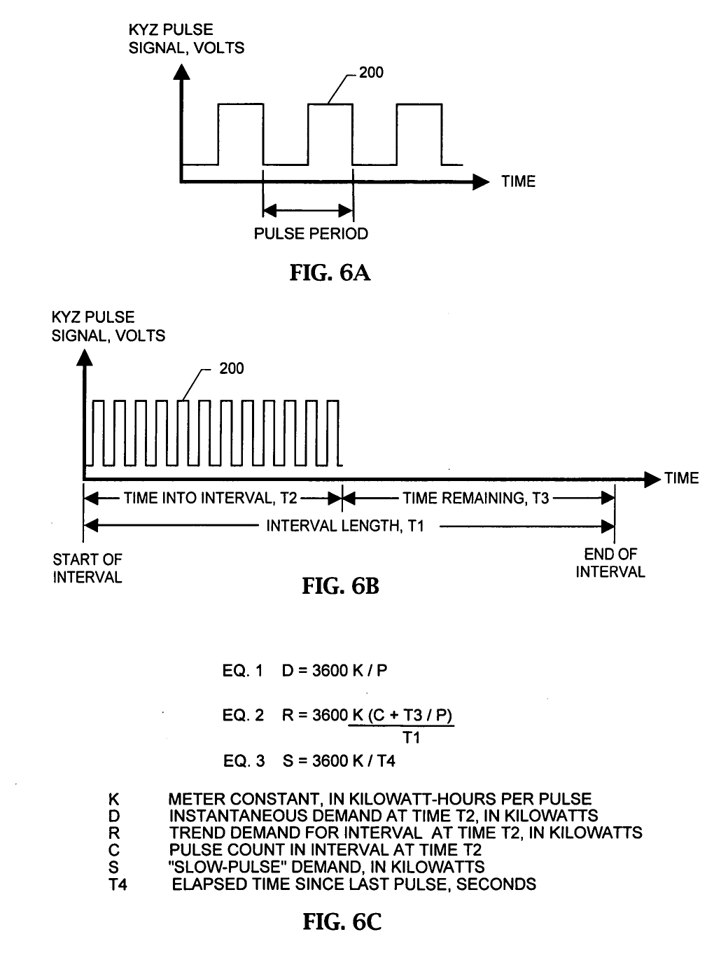

FIGS. 6A, 6B and 6C illustrate an algorithm by which the pulse transponder/logger of the second alternative embodiment derives useful measurements of electrical demand from KYZ pulses. FIG. 6A is a graph of voltage versus time of typical KYZ pulses 200, which are square waves alternating between a higher and a lower voltage level. FIG. 6A also shows the pulse period, which is the elapsed time from one edge of a pulse to the next corresponding edge. The measurement must not be taken from the falling-edge to rising-edge, or vice versa, because the pulse initiator 122 may be of a design that produces asymmetric pulses. The pulse frequency depends upon the electrical demand upon the meter and a meter constant, K, which is the amount of energy metered, in kilowatt-hours, for each pulse produced. Typically, the pulse frequency is one to several pulses per second when the customer's facility is at its maximum demand.

FIG. 6B is an elongation of FIG. 6A, encompassing an entire metering interval. In FIG. 6B the interval is in progress, and a number of pulses have accumulated. In demand response, the objective will be to limit the demand, that is, the pulse count during that interval, to some maximum value. Unlike the pulse period measurement, the pulse count preferably counts both rising and falling edges because doing so doubles the resolution.

FIG. 6C shows three equations that are useful in managing demand in real time within an interval. EQ. 1 calculates the instantaneous demand from pulse period, which is actually an average over the multiple 60-Hertz current cycles encompassed by a KYZ pulse. Starting electrical motors and other operations may cause brief spikes in the demand. Therefore, may be is preferable to apply EQ. 1 to several consecutive pulses and ignore the obvious spikes. EQ. 2 calculates the trend demand for the interval, which takes in account both the usage already accumulated in the interval and an estimate of usage for the remainder of the interval, which is extrapolated from instantaneous demand. EQ. 3 calculates the “slow pulse” demand, S, when the demand drops to a very low level. Since the pulses will be generated very slowly, the pulse period may stretch to the point where the pulse timer overflows. If more than a specified period passes after a pulse arrives, the value of S drops asymptotically until the next pulse arrives.

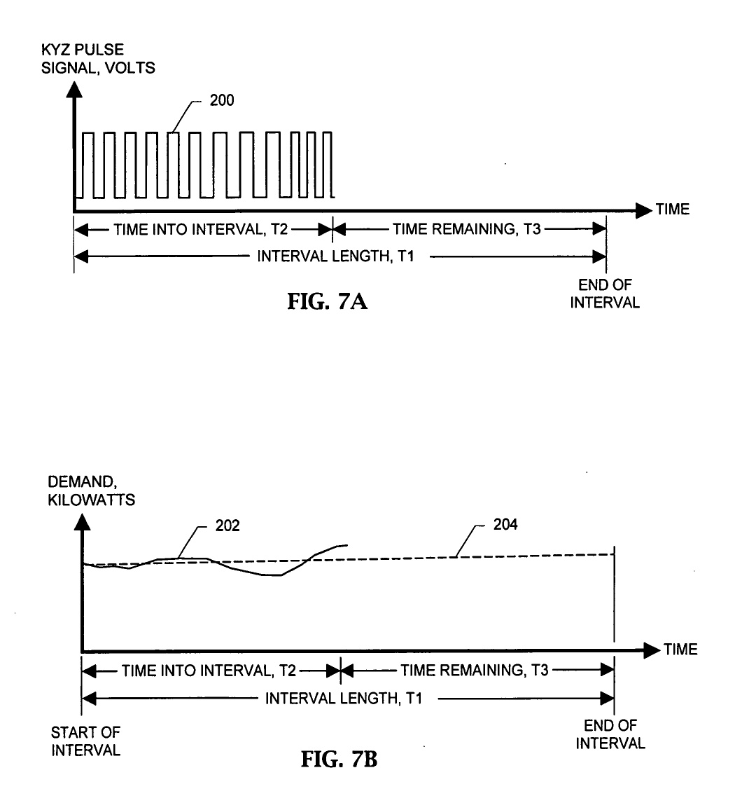

FIG. 7A and FIG. 7B depict the application of linear regression to determining the trend demand for a metering interval. Referring to FIG. 7A, instantaneous demand 202 can vary randomly over short timeframes, which would cause the trends calculated in FIG. 6C difficult to apply. This embodiment would calculate a linear regression trend 204 from a sampling of recently captured instantaneous demand values.

In a third alternative embodiment, digital outputs are incorporated into the pulse transponder/logger 120 described in [0051] for the purposes of directly controlling the customer's electrical equipment and lighting within the premises 50, dispatching on-site electrical generation within the premises, and for other similar purposes. The customer, or the utility, or both, could control the digital outputs.

Referring to FIG. 7, a fourth alternative embodiment places the software module 104, which composes the local web pages 106, in the microcontroller 130 instead of the computer 38. This embodiment would be applicable where the microcontroller is capable of composing and serving web pages, which is within the realm of current art.

Referring to FIG. 3, a fifth alternative embodiment is that the customer's computer 38 transmits real-time usage and demand data to the utility in real time or near-real time so that the utility can verify demand response, or for other purposes. Such transmission takes place through the second network 36, provided it is a low-latency data path.

What is claimed is:

1. A method for providing comprehensive electrical usage and demand data comprising:
an electronic energy information system according to certain of the prior art, comprising:
an electric meter operative to:
measure electrical usage and demand at the premises in which it is installed; and
communicate resulting measurements as data through an attached network;
a data server operative to:
retrieve energy usage and demand data from the electric meter through a first network; and
process the data into one or a plurality of web pages of a first group; and store said web page or pages; and
an end-user terminal operative to:
communicate with the server and retrieve the web page or pages of the first group through a second network; and
display the Web page or pages in meaningful and usable form;
wherein:
the meter is one of a plurality of similar meters installed in geographically dispersed locations;
the end-user terminal is one of a plurality of similar end-user terminals similarly dispersed; and
technical or economic considerations prevent the first network, the second network, or both from transporting web pages to end-user terminal timely for proactive management of energy utilization at said premises; and
wherein, the improvement that is claim 1 of the present invention comprises:
a third network through which the end-user terminal is operative to retrieve energy usage and demand data directly from the electric meter;
a software module within the end-user terminal operative to process the data retrieved through third network into one or a plurality of web pages of the second group; and
hyperlinks within web pages of the each of the first and second group operative to navigate to web pages of the other group;
whereby, the web pages of the first and second groups comprise comprehensive energy usage and demand data, including data presented timely for proactive management of energy utilization at said premises.

2. A method for providing comprehensive electrical usage and demand data comprising:
an electronic energy information system according to certain of the prior art, comprising:
an electric meter operative to:
measure electrical usage and demand at the premises in which it is installed; and
generate a stream of electrical pulses, generally known as kyz pulses, wherein each pulse represents a predetermined quantity of electrical usage;
a data server operative to:
retrieve energy usage and demand data from the electric meter through a first network;
process the data into one or a plurality of web pages of a first group; and store said web page or pages; and
an end-user terminal operative to:
communicate with the server and retrieve the web page or pages of the first group through a second network; and
display the Web page or pages in meaningful and usable form; and
wherein:
the meter is one of a plurality of similar meters installed in geographically dispersed locations;
the end-user terminal is one of a plurality of similar end-user terminals similarly dispersed; and
technical or economic considerations prevent the first network, the second network, or both from transporting web pages to end-user terminal timely for proactive management of energy utilization at said premises; and
wherein, the improvement that is claim 2 of the present invention comprises:
a pulse transponder/logger operative to:
receive kyz pulses from the electric meter
log into data memory the numbers of kyz pulses occurring in each of a sequence of time intervals of known correlation to local clock time and date;
interpret the width of individual kyz pulses as instantaneous electric demand;
perform certain algorithms to determine trend demand within each time interval;
transmit logged interval demand, instantaneous demand, and trend demand into an attached network; and
a third network through which the end-user terminal is operative to retrieve energy usage and demand data directly from the pulse transponder/logger;
a software module within the end-user terminal operative to process the data retrieved through third network into one or a plurality of web pages of the second group; and
hyperlinks within web pages of the each of the first and second group operative to navigate to web pages of the other group;
whereby, the web pages of the first and second groups comprise comprehensive energy usage and demand data, including data presented timely for proactive management of energy utilization at said premises.

3. The method claimed in claim 1 wherein the software module is located within the electric meter.

4. The method claimed in claim 2 wherein the software module is located within the electric meter.

5. The method claimed in claim 2 wherein the pulse transponder/logger is operative to control electrical loads or dispatch one or more on-site electrical generators.

6. The method claimed in claim 2 wherein the software module resides in the pulse transponder/logger rather than the end-user terminal.

7. The method claimed in claim 1 wherein the end-user terminal transmits electrical usage and demand data in real time through the second network.

8. The method claimed in claim 2 wherein the end-user terminal transmits electrical usage and demand data in real time through the second network.
